(19) United States
(12) Patent Application Publication
(10) Pub. No.: US 2013/0149168 A1
(43) Pub. Date: Jun. 13, 2013

(54) MOUNTING APPARATUS FOR FAN

(71) Applicant: ZHENG-HENG SUN, Tu-Cheng (TW)

(72) Inventor: ZHENG-HENG SUN, Tu-Cheng (TW)

(73) Assignee: HON HAI PRECISION INDUSTRY CO., LTD., Tu-Cheng (TW)

(21) Appl. No.: 13/337,263

(22) Filed: Dec. 26, 2011

(30) Foreign Application Priority Data
Dec. 12, 2011 (CN) 201110411710.X

(51) Int. Cl. F04D 29/00; H05K 7/20; F16M 13/00

(52) U.S. Cl. 416/244 R; 248/674

(57) ABSTRACT

A mounting apparatus is used for detachably mounting a fan in a chassis. The chassis includes a sidewall defining a locking slot. The mounting apparatus includes a bracket fixing the fan, and a locking member sandwiched between the fan and the bracket. The bracket defines a through slot. The locking member includes a locking portion extending through the through slot of the bracket to engage in the locking slot of the chassis.

### BACKGROUND

1. Technical Field

The present disclosure relates to an apparatus for mounting a fan.

2. Description of Related Art

An electronic device often uses a fan for heat dissipation. The fan is installed in a case mounted in the electronic device. However, the fan is often fixed to the case through a plurality of screws, which is inconvenient.

### BRIEF DESCRIPTION OF THE DRAWINGS

Many aspects of the present embodiments can be better understood with reference to the following drawings. The components in the drawing are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of a mounting apparatus for a fan in accordance with an exemplary embodiment.

FIG. 2 is similar to FIG. 1, but viewed from another aspect.

FIG. 3 is an assembled view of part of elements of FIG. 2.

FIG. 4 is a partially assembled view of FIG. 1.

FIG. 5 is an assembled, isometric view of FIG. 1.

### DETAILED DESCRIPTION

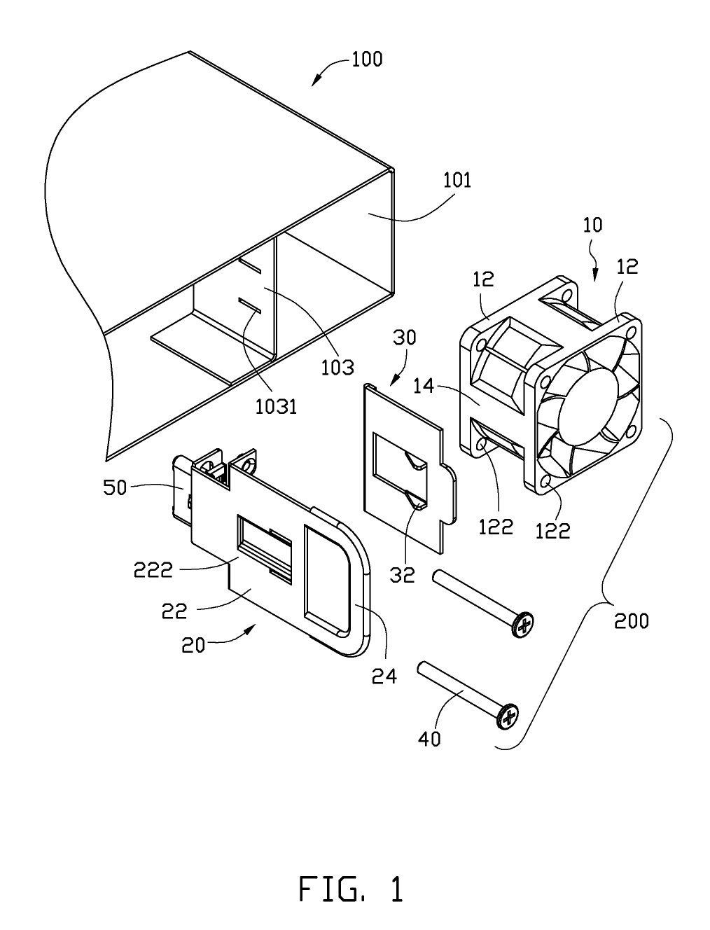

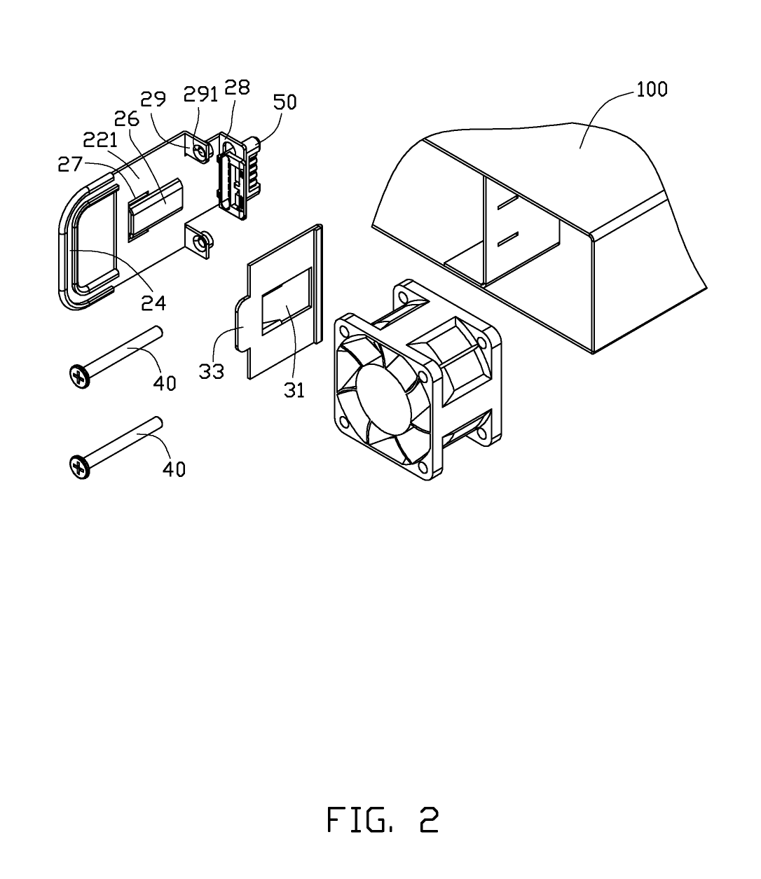

FIG. 1 and FIG. 2, are embodiments of a mounting apparatus 200 for mounting a fan 10 in a chassis 100.

The chassis 100 includes a receiving portion 101 for receiving the fan 10. The receiving portion 101 includes a sidewall 103 defining two parallel locking slots 1031.

The mounting apparatus 200 includes a bracket 20, a locking member 30, and two fasteners 40. In this embodiment, the fasteners 40 are bolts.

The fan 10 includes two mounting plates 12 each defining four mounting holes 122 in four corners. An engaging portion 14 is formed between every two opposite sides of the mounting plates 12.

The bracket 20 includes a base plate 22. A handle 24 is formed from a first end of the base plate 22. The base plate 22 includes a first side surface 221 and a second side surface 222 opposite to the first side surface 221. A raised portion 26 protrudes from the first side surface 221. Two through slots 27 are defined in the base plate 22, extending through the first and second side surfaces 221 and 222, and at opposite sides of the raised portion 26. A clipping portion 28 perpendicularly extends from a middle of a second end of the base plate 22. A connector 50 is fixed to the clipping portion 28. Two fixing pieces 29 extend perpendicularly from the second end of the base plate 22, respectively at opposite sides of the clipping portion 28. Each fixing piece 29 defines a fixing hole 291.

The locking member 30 defines a through hole 31 in a center. Two triangular locking portions 32 extend from the locking member 30, at opposite sides of the through hole 31. An operation portion 33 extends from one end of the locking member 30.

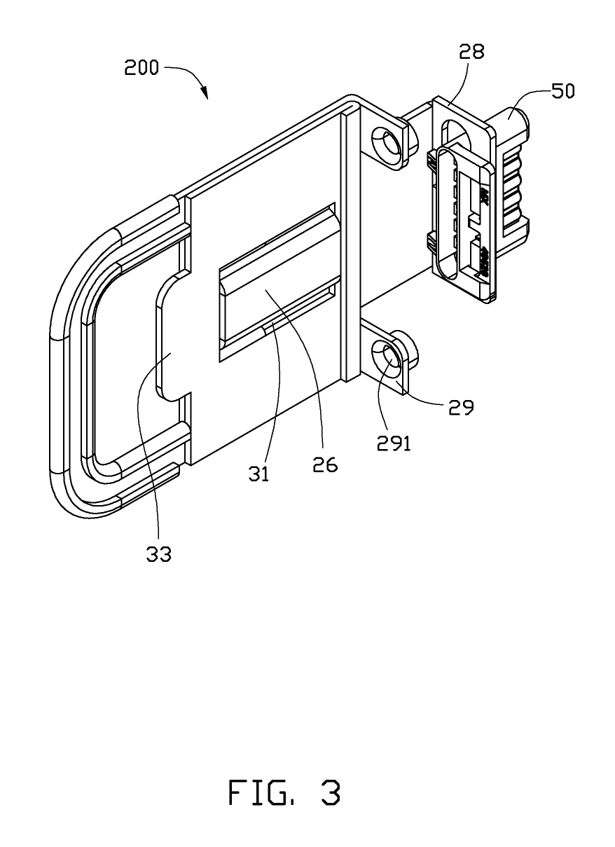

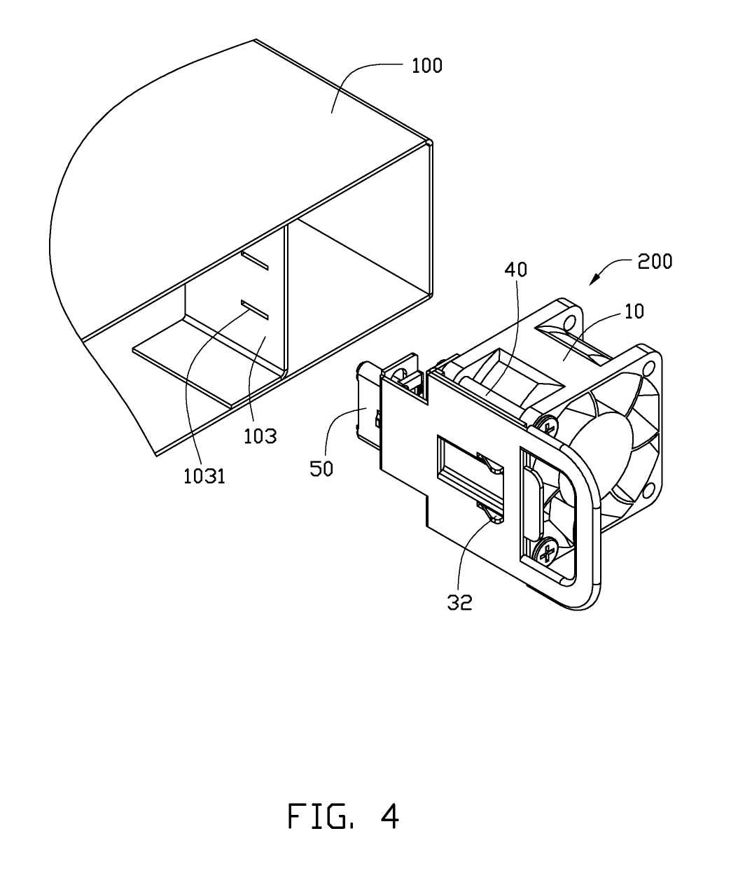

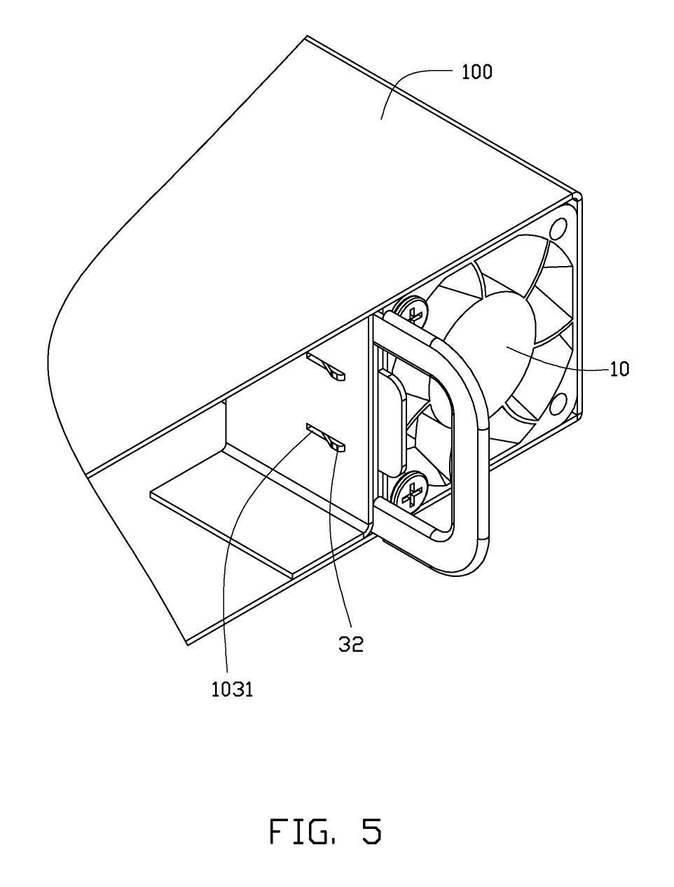

FIG. 3 to FIG. 5, in assembly, the locking member 30 is attached to the first side surface 221. The raised portion 26 extends through the through hole 31. The locking portions 32 extend through the through slots 27 to be exposed out of the second side surface 222. The fan 10 is attached to the bracket 20, with the mounting plates 12 perpendicular to the base plate 22. One mounting plate 12 abuts against the mounting pieces 29, with two mounting holes 122 adjacent to the bracket 20 aligning with the fixing holes 291 respectively. The fasteners 40 extend through the corresponding mounting holes 122 to screw into the corresponding fixing holes 291. Therefore, the fan 10 is fixed to the bracket 20. The raised portion 26 engages with one of the engaging portions 14. A space between the first side surface 221 and the fan 10 is enough for deforming the locking member 30 to release the locking portions 32 from the locking slots 1031. The connector (not shown) of the fan 10 is inserted into the connector 50.

When assembling the fan 10 to the receiving portion 101, the locking portions 32 abut against the sidewall 103 to deform the locking member 30 toward the fan 10. When the locking portions 32 align with the corresponding locking slots 1031, the locking member 30 is restored to force the locking portions 32 to engage in the locking slots 1031. The connector 50 is connected to a circuit board (not shown) in the chassis 100.

In disassembling the fan 10, the handle 24 is pressed toward the operation portion 33 to deform the locking member 30, until the locking portions 32 are released from the locking slots 1031. Therefore, the fan 10 together with the bracket 20 and the locking member 30 can be pulled out of the chassis 100.

Even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A mounting apparatus for a fan, comprising:
a chassis comprising a receiving portion with a sidewall defining a locking slot;
a bracket for fixing the fan, and defining a through slot; and
a locking member sandwiched between the fan and the bracket, wherein the locking member comprises a locking portion extending through the through slot of the bracket to detachably engage in the locking slot of sidewall of the chassis.

2. The mounting apparatus as claimed in claim 1, wherein the bracket comprises a base plate, the base plate comprises a first side surface and a second side surface opposite to the first side surface, a raised portion protrudes from the first side surface, the locking member defines a through hole, the raised portion extends through the through hole to abut against the fan.

3. The mounting apparatus as claimed in claim 2, wherein a handle is formed from a first end of the base plate.

4. The mounting apparatus as claimed in claim 2, wherein the through slot is defined in the base plate and beside the raised portion.

5. The mounting apparatus as claimed in claim 2, wherein a clipping portion extends from a middle of one end of the base plate, a connector is fixed to the clipping portion for connecting the fan.

6. The mounting apparatus as claimed in claim 2, wherein two fixing pieces extend perpendicularly from one end of the base plate, each of the fixing pieces defines a fixing hole for fixing the fan.

7. The mounting apparatus as claimed in claim 1, wherein the locking portion is substantially triangular.

8. A fan module, comprising:
a fan;
a bracket fixing the fan, and defining a through slot; and
a locking member sandwiched between the fan and the bracket, wherein the locking member comprises a locking portion extending through the through slot of the bracket.

9. The fan module as claimed in claim 8, wherein the bracket comprises a base plate, the base plate comprises a first side surface and a second side surface opposite to the first side surface, a raised portion protrudes from the first side surface, the locking member defines a through hole, the raised portion extends through the through hole to abut against the fan.

10. The fan module as claimed in claim 9, wherein a handle is formed from a first end of the base plate.

11. The fan module as claimed in claim 9, wherein the through slot is defined in the base plate, beside the raised portion.

12. The fan module as claimed in claim 9, wherein a clipping portion extends in a substantially perpendicular manner from a middle of one end of the base plate, a connector is fixed to the clipping portion for connecting the fan.

13. The fan module as claimed in claim 9, wherein two fixing pieces extend perpendicularly from one end of the base plate, each of the fixing pieces defines a fixing hole, the fan comprises two mounting plates each defining four mounting holes in four corners, two fasteners extend through two of the mounting holes adjacent to the bracket to screw into the corresponding fixing holes.

14. The fan module as claimed in claim 13, wherein an engaging portion is formed between every two opposite sides of the mounting plates, the raised portion engages with one of the engaging portions adjacent to the bracket.

15. An assembly, comprising:
a chassis comprising a receiving portion, the receiving portion comprising a sidewall defining a locking slot;
a fan;
a bracket defining a through slot, wherein the fan is fixed to the bracket; and
a locking member sandwiched between the fan and the bracket, wherein the locking member comprises a locking portion extending through the through slot of the bracket.

16. The assembly as claimed in claim 15, wherein the bracket comprises a base plate, the base plate comprises a first side surface and a second side surface opposite to the first side surface, a raised portion protrudes from the first side surface, the locking member defines a through hole, the raised portion extends through the through hole to abut against the fan.

17. The assembly as claimed in claim 16, wherein a handle is formed from a first end of the base plate.

18. The assembly as claimed in claim 16, wherein a clipping portion extends from a middle of one end of the base plate, a connector is fixed to the clipping portion for connecting the fan.

19. The assembly as claimed in claim 16, wherein two fixing pieces extend perpendicularly from one end of the base plate, each of the fixing pieces defines a fixing hole, the fan comprises two mounting plates each defining four mounting holes in four corners, two fasteners extend through two of the mounting holes adjacent to the bracket to screw into the corresponding fixing holes.

20. The assembly as claimed in claim 19, wherein an engaging portion is formed between every two opposite sides of the mounting plates, the raised portion engages with one of the engaging portions adjacent to the bracket.
